(19) United States
(12) Patent Application Publication
(10) Pub. No.: US 2004/0071176 A1
(43) Pub. Date: Apr. 15, 2004

(54) Semiconductor laser device and method for manufacturing the same

(76) Inventors: Masayuki Ohta, Nara (JP); Shinji Kaneiwa, Nara (JP); Noboru Oshima, Nara (JP)

Correspondence Address: MORRISON & FOERSTER LLP, 755 PAGE MILL RD, PALO ALTO, CA, 94304-1018, US

(21) Appl. No.: 10/650,181

(22) Filed: Aug. 27, 2003

(30) Foreign Application Priority Data
Aug. 30, 2002 (JP) 2002-255018

(51) Int. Cl. H01L 21/00; H01S 5/00

(52) U.S. Cl. 372/44; 438/22

(57) ABSTRACT

A method for manufacturing a semiconductor laser device, comprising the steps of: forming an electrode pattern on an upper surface of a semiconductor wafer stacked at least a light emission layer; cutting the resultant semiconductor wafer for predetermined width to yield a plurality of semiconductor bars; and sectioning the semiconductor bars into a desired size to form semiconductor laser devices having a pair of cleavage surfaces which are parallel to a chip-width direction and distant from each other by a predetermined resonator length, wherein the electrode pattern formed in the step of forming an electrode pattern is continuous at least in a resonator-length direction.

### CROSS-REFERENCE TO RELATED APPLICATION

This application is related to Japanese application No. 2002-255018 filed on Aug. 30, 2002, whose priority is claimed under 35 USC § 119, the disclosure of which is incorporated by reference in its entirety.

### BACKGROUND OF THE INVENTION

1. Field of the Invention

The present invention relates to a semiconductor laser device and a method for manufacturing the semiconductor laser device. More particularly, it relates to an electrode pattern of a semiconductor laser device.

2. Description of Related Art

High-power semiconductor laser devices used for the reading and writing of data from and to optical data recording media such as a CD-R/RW and a DVD-R/RW have different optimal resonator lengths determined in accordance with each kind of the optical data recording media, and the use of the semiconductor laser device of which resonator length is not suitable for a target optical data recording medium will cause SCOOP errors (noise due to return light). Therefore, various kinds of the optical data recording media require semiconductor laser devices (laser chips) having optimal resonator lengths.

These semiconductor laser devices have been conventionally manufactured as follows: First, on an upper surface of a semiconductor wafer stacked at least a light emission layer, a plurality of electrode pattern pieces 72 each having a smaller size than that of a chip to fit in it (FIG. 9) are formed at a fixed pitch in a resonator-length direction of arrow A and at a fixed pitch in a chip-width direction of arrow B. Next, the resultant wafer is cut along the chip-width direction of arrow B for every length equal to a fixed resonator length L into a plurality of laser bars. Here, intermediate positions between the adjacent electrode pattern pieces 72 on the upper surface of the wafer serve as guides for the cutting. Subsequently, the laser bars are sectioned for every length equal to a fixed chip width W into individual semiconductor laser devices (laser chips) 70 shown in FIG. 9 (see Japanese Unexamined Utility Model Publication No. Hei 6(1994)-79172). The laser chip 70 includes: a semiconductor layer portion 71 of a laminate structure of a plurality of semiconductor layers having cleavage planes 73 and 74 formed in contact with the respective edges of the semiconductor layer portion 71 extending in the chip-width direction of arrow B; and the electrode pattern piece 72 formed on an upper surface of the semiconductor layer portion 71. The resonator length L of the laser chip 70 in the resonator-length direction of arrow A is set to a fixed resonator length.

However, as mentioned above, in the conventional method for manufacturing a semiconductor laser device, since the electrode pattern pieces 72 each to fit into the chip having the predetermined resonator length L are individually produced, laser chips having different resonator lengths can not be manufactured from the same wafer. In other words, if laser chips having a resonator length L′ different from the predetermined resonator length L are manufactured as shown in FIG. 9 and FIGS. 10(a) and (b), laser chips 81 yield each of which has an electrode piece 82 separated into two. With the laser chips 81, recognition errors will occur in a be scribing step and therefore device defectiveness will be caused. For this reason, for manufacturing a different kind of laser chip, it has been required to form on a wafer electrode pattern pieces each allowed to correspond to the resonator length of the chip, and therefore it has been impossible to be flexible in response to changes in production plan of laser chips.

### SUMMARY OF THE INVENTION

The present invention has been made in view of the above circumstances and one of the main purposes thereof is to provide a method for manufacturing a semiconductor laser device which allows laser chips having different resonator lengths to be manufactured from the same semiconductor wafer and to provide a semiconductor laser device manufactured by the method.

The present invention provides a method for manufacturing a semiconductor laser device, comprising the steps of: forming an electrode pattern on an upper surface of a semiconductor wafer stacked at least a light emission layer; cutting the resultant semiconductor wafer for predetermined width to yield a plurality of semiconductor bars; and sectioning the semiconductor bars into a desired size to form semiconductor laser devices having a pair of cleavage surfaces which are parallel to a chip-width direction and distant from each other by a predetermined resonator length, wherein the electrode pattern formed in the step of forming an electrode pattern is continuous at least in a resonator-length direction.

Also, the present invention provides a semiconductor laser device, comprising: a semiconductor layer portion which includes at least a light emission layer (active layer) and has a pair of cleavage surfaces which are parallel to a chip-width direction and distant from each other by a predetermined resonator length; and an electrode pattern piece formed on an upper surface of the semiconductor layer portion, wherein the electrode pattern piece comes in contact with the pair of cleavage planes at both of the edges of the electrode pattern piece extending in a chip-width direction.

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic perspective view illustrating a semiconductor laser device according to Embodiment 1 of the present invention;

FIG. 2 is a plan view showing the device according to Embodiment 1;

FIG. 3 is a view for explaining a step of cutting a wafer for manufacturing the device according to Embodiment 1;

FIG. 4 is a plan view illustrating a semiconductor laser device according to Embodiment 2 of the present invention;

FIG. 5 is a plan view illustrating a semiconductor laser device according to Embodiment 3 of the present invention;

FIG. 6 is a plan view illustrating a semiconductor laser device according to Embodiment 4 of the present invention;

FIG. 7 is a plan view illustrating a semiconductor laser device according to Embodiment 5 of the present invention;

FIG. 8 is a plan view illustrating a semiconductor laser device according to Embodiment 6 of the present invention;

FIG. 9 is a plan view of a conventional semiconductor laser device;

FIGS. 10(a) and (b) are plan views of electrode pattern pieces formed on chips by a conventional method for manufacturing a semiconductor laser device so that the electrode pattern pieces each have a resonator length different from a predetermined resonator length.

### DESCRIPTION OF THE PREFERRED EMBODIMENTS

According to the present invention, the semiconductor wafer may be any conventional wafers which are usable as leaser diodes, typically Si, SiGe or GaAs wafer and the semiconductor wafer to form the electrode pattern by the present process has preferably at least a light emission layer on its one surface and an electrode on its another surface. The term “cleavage surface” means a cross section obtained by sectioning the semiconductor wafer along the chip-width direction. The term “chip-width direction” means a direction parallel to the cleavage planes of the semiconductor laser device for emitting laser light. The term “resonator-length direction” means a direction perpendicular to the cleavage plane s.

According to the present invention, the cutting of the wafer and the sectioning of the semiconductor bars may be carried out by the following process \mathring{1} or \mathring{2}:

\mathring{1} The semiconductor wafer having the electrode pattern is cut for every length equal to a fixed resonator-length measured along the resonator-length direction into a plurality of semiconductor bars (laser bars) longitudinally extending in the chip-width direction. The bars thus obtained are sectioned (cut) for every length equal to a fixed chip width into semiconductor laser devices of a fixed chip size.

\mathring{2} The semiconductor wafer having the electrode pattern is cut for every length equal to the fixed chip width measured in the chip-width direction into a plurality of semiconductor bars longitudinally extending in the resonator-length direction. The bars thus obtained are sectioned (cut) for every length equal to the fixed resonator length into semiconductor laser devices of a fixed chip size.

According to the method for manufacturing a semiconductor laser device of the present invention, since the continuous electrode pattern (having no break) in the resonator-length direction is formed on the wafer in the step of forming an electrode pattern, it can be cut for every desired resonator length during the above process \mathring{1} or \mathring{2}. In other words, the cutting pitch of the electrode pattern can be changed. Therefore, semiconductor laser devices having different resonator lengths can be manufactured from the same wafer and as a result, it is possible to be flexible in response to change in plans to laser chips of a different kind.

According to the method for manufacturing a semiconductor laser device of the present invention, the formation of an electrode pattern may be carried out by the following process \mathring{3}, \mathring{4} or \mathring{5}:

\mathring{3} A plurality of electrode patterns are formed in a plurality of rows at a fixed row pitch in the chip-width direction with a plurality of markers in a predetermined shape being formed at a pitch not greater than the resonator length at one or both of the edges of the electrode patterns extending in the resonator-length direction. With this constitution, the electrode patterns are formed continuously in the resonator-length direction on the wafer, so that they can be cut for every desired resonator length during the process \mathring{1} or \mathring{2}. Also, since the markers in a predetermined shape are formed integrally with the electrode pattern on one or both of the edges of the electrode patterns extending in the resonator-length direction, it is possible to identify the resultant laser chip and distinguish a main surface of the chip for emitting laser light from the other surfaces on the basis of the shape, number, or location of the markers or the combination thereof. As a result, the orientation of the main surface for emitting laser light can be established when the laser chip is mounted on a heat sink or a package.

\mathring{4} The electrode pattern is formed on the substantially entire surface of the semiconductor wafer with a plurality of openings to be markers being formed on hypothetical lines sectioning the electrode pattern at intervals each of the chip width and at the pitch not greater than the resonator length in the resonator-length direction. With this constitution as well, the electrode pattern is formed continuously in the resonator-length direction on the wafer, so that it can be cut for every desired resonator length during the process \mathring{1} or \mathring{2}. Also, the presence of the openings to be markers assists in detecting with ease and certainty the hypothetical lines sectioning the electrode pattern.

\mathring{5} The electrode pattern is formed on the substantially entire surface of the semiconductor wafer with a plurality of markers being formed at corresponding positions of laser light emitting channels of the electrode pattern in the chip-width direction at the pitch equal to the chip width and at the pitch not greater than the resonator length in the resonator-length direction. With this constitution as well, the electrode pattern is formed continuously in the resonator-length direction on the wafer, so that it can be cut for every desired resonator length during the process \mathring{1} or \mathring{2}. Also, the orientation of the laser light emitting channel can be easily and accurately established by the presence of the markers when the resultant laser chip is mounted on a heat sink or a package.

In the process \mathring{3}, the pair of markers at the respective edges of the electrode pattern piece extending in the resonator-length direction may be symmetric with respect to a center line of the electrode pattern piece extending in the resonator-length direction and asymmetric (in right triangle or trapezoid for example) with respect to a hypothetical line of the electrode pattern piece extending in the chip-width direction bisectioning the overall length of the marker. With this constitution, it is possible to distinguish the main surface for emitting laser light from the other surfaces of the laser chip on the basis of geometrical features of the pair of markers. A detailed explanation will be later given in the section of

### DESCRIPTION OF THE PREFERRED EMBODIMENTS

In the process \mathring{3}, in a case where the markers are formed at only one of the edges of the electrode pattern piece extending in the resonator-length direction, the discrimination of the cleavage planes from each other can be made in such a manner that the resultant chip is placed with the marker(s) in front so that the main surface for emitting laser light can be found at the right hand for example.

In the process \mathring{3}, the plurality of markers may be formed at a fixed pitch with the overall lengths of the plurality of markers in the resonator-length direction each being set to be equal to L/n, wherein L is a resonator length and n is an integer not smaller than one, and being set to be equal to the pitch of the markers. With this constitution, the resonator length can be easily determined by calculating the number of the markers within one chip so that mingling of different kinds of semiconductor laser devices can be prevented or different kinds of mingled semiconductor laser devices can be separated.

In the process \mathring{3}, the marker may be set so that the ratio of its overall length in the resonator-length direction to its maximum length in the chip-width direction is 1:5 to 5:1. In a case where the laser chip has a resonator length of 700 to 900 μm and a chip width of 200 to 250 μm, the overall length of the marker in the resonator-length direction may be 30 to 300 μm and the maximum length of the marker in the chip-width direction 150 to 30 μm. With this constitution, since the geometric configuration of the markers can be readily discerned through visual observation, misidentification of the laser chip can be effectively prevented. However, if the marker is set so that the ratio of its overall length in the resonator-length direction to its maximum length in the chip-width direction deviates from the range of 1:5 to 5:1, there arises a possibility that the semiconductor laser device may be misidentified because the geometric configuration of the markers is difficult to discern.

The present invention will now be explained in detail based on the preferred embodiments shown in the drawings. It should be understood that the present invention is not limited to the embodiments.

Embodiment 1

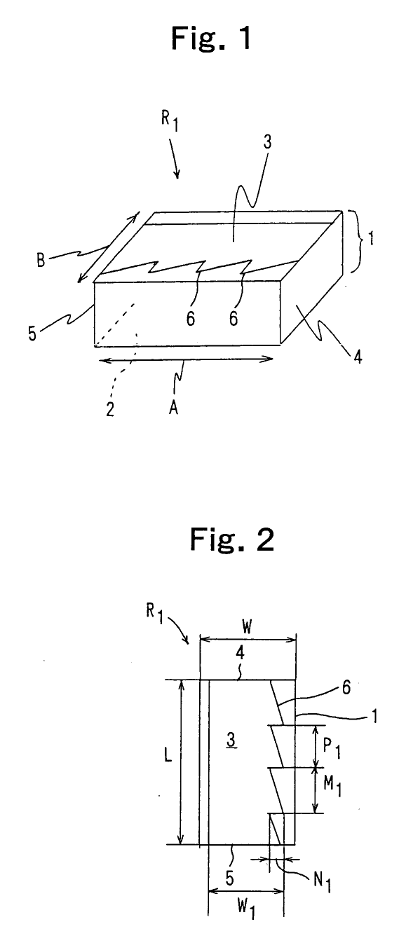

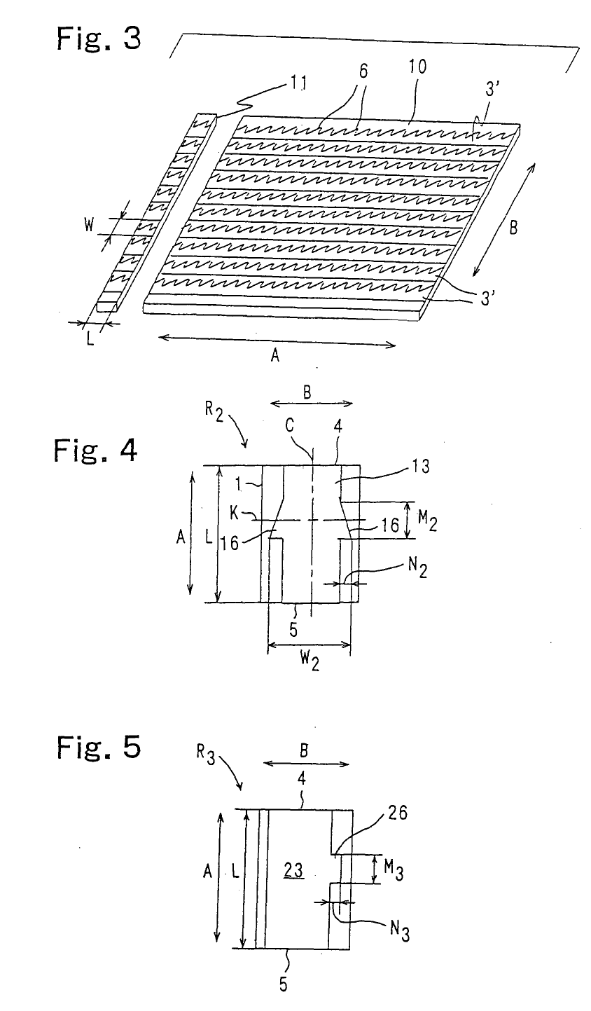

FIG. 1 is a schematic perspective view illustrating a semiconductor laser device R₁ according to Embodiment 1 of the present invention. FIG. 2 is a plan view showing the device R₁ according to Embodiment 1. FIG. 3 is a view for explaining a step of cutting a wafer for manufacturing the device R₁ according to Embodiment 1.

The semiconductor laser device (laser chip) R₁ comprises: a semiconductor layer portion 1 of a laminate structure of a plurality of semiconductor layers including a light emission layer which semiconductor layer portion 1 has an electrode portion 2 formed on a lower surface thereof; and an electrode pattern piece 3 formed on an upper surface of the semiconductor layer portion 1. The semiconductor layer portion 1 has a pair of cleavage planes 4 and 5 in parallel to a chip-width direction of arrow B. Arrow A in FIG. 1 indicates a resonator-length direction. The semiconductor laser device R₁ has a resonator length L of, for example, 800 μm in the resonator-length direction of arrow A and a chip width W of, for example, 230 μm.

The electrode pattern piece 3 comes in contact with the pair of cleavage planes 4 and 5 at both of the edges of the electrode pattern piece 3 extending in the chip-width direction of arrow B; has a plurality of (in this case, four) right triangle markers 6 formed at a fixed pitch in saw blade at one of the edges of the electrode pattern piece 3 extending in the resonator-length direction of arrow A; and is formed straight at the other edge extending in the resonator-length direction of arrow A. Also, the electrode pattern piece 3 has an overall width W₁ in the chip-width direction of arrow B which is smaller than a chip width W of the semiconductor layer portion 1 and which is, for example, 170 μm.

The marker 6 is set so that its overall length M₁ in the resonator-length direction of arrow A is, for example, 200 μm and its maximum length N₁ in the chip-width direction of arrow B is, for example, 80 μm, so that the ratio of the overall length M₁ to the maximum length N₁ is 5:2. The overall length M₁ is set to be equal to L/4 (L is a resonator length) and equal to a pitch P₁ of the markers 6.

With this construction of the semiconductor laser device R₁ according to Embodiment 1, the electrode pattern piece 3 has the markers 6 at only one of the edges of the electrode pattern piece 3 extending in the resonator-length direction of arrow A. Accordingly, it is possible to make an easy discrimination of the cleavage planes 4 and 5 from each other in such a manner that the device R₁ is placed with the markers 6 in front so that the cleavage plane 4 (for example, the main surface for emitting laser light) can be found at the right hand and the cleavage plane 5 at the left hand. In packaging of the device R₁, this assists in checking the orientation of the device R₁ which is required if the cleavage planes 4 and 5 are allowed to have asymmetrical coatings so as to emit different intensities of laser light. Moreover, the markers 6 each having the overall length M₁ equal to L/n (L is the resonator length and n is an integer which in this case is four) are formed at the pitch P₁ equal to the overall length M₁. Accordingly, the resonator length L can be easily determined by calculating the number of the markers 6 within one chip so that mingling of semiconductor laser devices of different kinds can be prevented. Here, the marker 6 is designed such that the ratio of the overall length M₁ in the resonator-length direction of arrow A to the maximum length N₁ in the chip-width direction of arrow B is within the range of 1:5 to 5:1. Accordingly, the geometric configuration of the markers 6 can be discerned through visual observation so that misidentification of the semiconductor laser device R₁ can be prevented.

An explanation will be given to a method for manufacturing the semiconductor laser device R₁ according to Embodiment 1.

First, electrode patterns 3′ are formed on an upper surface of a rectangular semiconductor wafer 10 of a laminate structure of a plurality of semiconductor layers including a light emission layer, as shown in FIG. 3. The electrode patterns 3′ each in the form of a continuous strip extending longitudinally in the resonator-length direction of arrow A are formed on the upper surface of the wafer 10 in rows at a row pitch equal to the fixed chip width W (see FIG. 3). Here, the electrode patterns 3′ each have the plurality of markers 6 in saw blade at one of the edges of the electrode patterns 3′ extending in the resonator-length direction of arrow A. The descriptions of shape, size and pitch of each marker are omitted since they are already given with reference to FIGS. 1 and 2. The electrode patterns 3′ may be formed by a known technique.

Next, the wafer 10 thus having the electrode patterns 3′ in rows is cut for every length equal to the fixed resonator length L {which in this case as seen in FIG. 2 is P₁ (marker pitch)×4} into a plurality of semiconductor bars (laser bars) 11. The resonator length L is the length that permits each of the resultant bars to have the exact length of four markers 6. Here, the loss by the cutting is not considered.

Subsequently, the bars 11 thus obtained are each sectioned for every length equal to the fixed chip width W into a plurality of semiconductor laser devices. The sectioning is carried out along hypothetical lines passing halfway between the adjacent electrode patterns 3′. Here again, the loss by the sectioning is not considered.

According to the method for manufacturing a semiconductor laser device of Embodiment 1, since the electrode patterns 3′ each in the form of a continuous strip longitudinally extending in the resonator-length direction of arrow A are formed on the upper surface of the wafer 10 in the step of forming an electrode pattern, the wafer can be cut for every desired resonator length. Thus, semiconductor laser devices having different resonator lengths can be manufactured from the same wafer. Moreover, in Embodiment 1, a case is given by way of illustration that the semiconductor laser devices R₁ are produced each of which has the resonator length L equivalent to the exact length of four markers 6. However, for manufacturing semiconductor laser devices having a resonator length different from the resonator length L, it is possible to manufacture semiconductor laser devices having a resonator length equivalent to the total length of an integral number of markers, for example, the total length of not less than five markers or the total length of not more than three markers. Also, it is possible to manufacture semiconductor laser devices having a resonator length not equivalent to the total length of an integral number of markers.

Embodiment 2

FIG. 4 is a plan view illustrating a semiconductor laser device R₂ according to Embodiment 2 of the present invention.

The device R₂ according to Embodiment 2 is identical to the device R₁ according to Embodiment 1 except that an electrode pattern piece 13 of the device R₂ is different in shape and arrangement from the electrode pattern piece 3 of the device R₁. Like elements are given like numerals and explanations therefore are omitted.

In the device R₂, the electrode pattern piece 13 has a pair of right triangle markers 16 at the respective edges of the electrode pattern piece 13 extending the resonator-length direction of arrow A. The marker 16 is set so that its overall length M₂ in the resonator-length direction of arrow A is, for example, 200 μm and its maximum length N₂ in the chip-width direction of arrow B is, for example, 40 μm, so that the ratio of the overall length M₂ to the maximum length N₂ is 5:1. The pair of markers 16 are symmetric with respect to a center line C of the electrode pattern piece 13 extending in the resonator-length direction of arrow A and asymmetric with respect to a hypothetical line K extending in the chip-width direction of arrow B bisectioning the overall length M₂ of the marker 16.

Thus, the electrode pattern piece 13 has the pair of right triangle markers 16 at the respective edges of the electrode pattern piece 13 extending the resonator-length direction of arrow A, the pair of markers being symmetric with respect to the center line C of the electrode pattern piece 13 extending in the resonator-length direction and asymmetric with respect to the hypothetical line K bisectioning the overall length M₂ of the marker 16. Accordingly, based on geometrical features of the pair of markers 16 such as the orientation of a slope and the position assumed by a top of each marker 16, it is possible to distinguish the main surface for emitting laser light from the other surfaces of the laser chip R₂.

According to the method for manufacturing a semiconductor laser device of Embodiment 2, electrode patterns are formed in rows on the upper surface of the semiconductor surface in the same manner as in Embodiment 1 (see FIG. 3) except that in Embodiment 2, the electrode patterns each have the plurality of markers 16 formed at a pitch equal to the fixed resonator length L at both of the edges of the electrode patterns extending in the resonator-length direction of arrow A. Then, the wafer is cut for every length equal to the fixed resonator length L into a plurality of semiconductor bars. The cutting is carried out along hypothetical lines passing between the adjacent markers. The bars thus obtained are each sectioned for every length equal to the fixed chip width W into a plurality of semiconductor laser devices. The sectioning is carried out along hypothetical lines passing halfway between the adjacent electrode patterns.

According to the method for manufacturing a semiconductor laser device of Embodiment 2 as well, since the electrode patterns are each in the form of a continuous strip longitudinally extending in the resonator-length direction of arrow A are formed on the upper surface of the wafer in the step of forming an electrode pattern, semiconductor laser devices having different resonator lengths can be manufactured from the same wafer, as in Embodiment 1. In Embodiment 2, however, the markers 16 are formed at the pitch equal to the fixed resonator length L. This means that if the wafer is cut to lengths shorter than the resonator length L, some of the resultant devices do not have any marker 16. Accordingly, for manufacturing semiconductor laser devices having a resonator length different from the resonator length L, it is preferred that the wafer is cut to lengths longer than the resonator length L so that devices obtained have a resonator length longer than the resonator length L. Thus, every device does not fail to have the marker 16 so that the distinction of the main surface for emitting laser light from the other surfaces can be ensured in the resultant device R₂.

Embodiment 3

FIG. 5 is a plan view illustrating a semiconductor laser device R₃ according to Embodiment 3 of the present invention.

In the device R₃, its elongated electrode pattern piece 23 has a rectangular marker 26 at one of the edges of the elongated electrode pattern piece 23 extending in the resonator-length direction of arrow A. The marker 26 is set so that its overall length M₃ in the resonator-length direction of arrow A is, for example, 300 μm and its maximum length N₃ in the chip-width direction of arrow B is, for example, 60 μm, so that the ratio of the overall length M₃ to the maximum length N₃ is 5:1.

According to the method for manufacturing a semiconductor laser device of Embodiment 3, electrode patterns are formed in rows on the upper surface of the semiconductor surface in the same manner as in Embodiment 1 (see FIG. 3) except that in Embodiment 3, the electrode patterns each have a plurality of markers 26 formed at the pitch equal to the fixed resonator length L at one of the edges of the electrode patterns extending in the resonator-length direction of arrow A. According to the method for manufacturing a semiconductor laser device of Embodiment 3 as well, since the electrode patterns each in the form of a continuous strip longitudinally extending in the resonator-length direction of arrow A are formed on the upper surface of the wafer in the step of forming an electrode pattern, semiconductor laser devices having different resonator lengths can be manufactured from the same wafer. In Embodiment 3, however, the markers 26 are formed at the pitch equal to the fixed resonator length L, as in Embodiment 2. This means that if the wafer is cut to lengths shorter than the resonator length L, some of the resultant devices do not have any marker 26. Accordingly, for manufacturing semiconductor laser devices having a resonator length different from the resonator length L, it is preferred that the wafer is cut to lengths longer than the resonator length L so that devices obtained have a resonator length longer than the resonator length L.

Embodiment 4

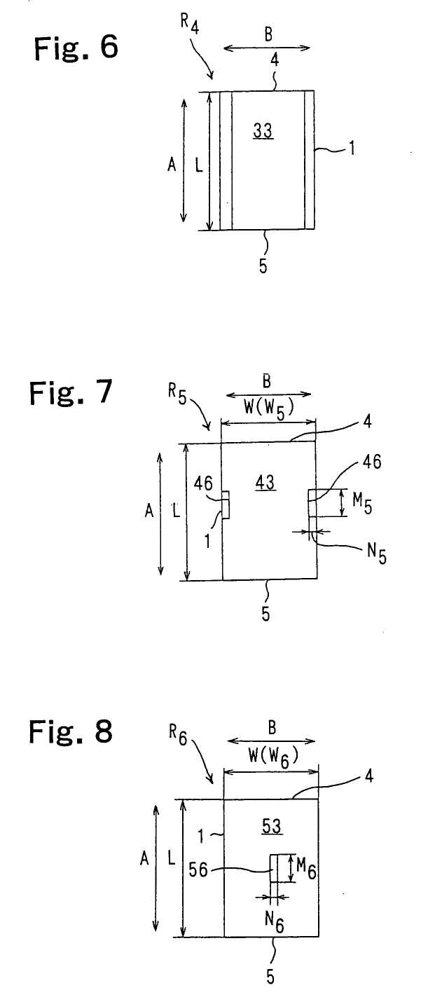

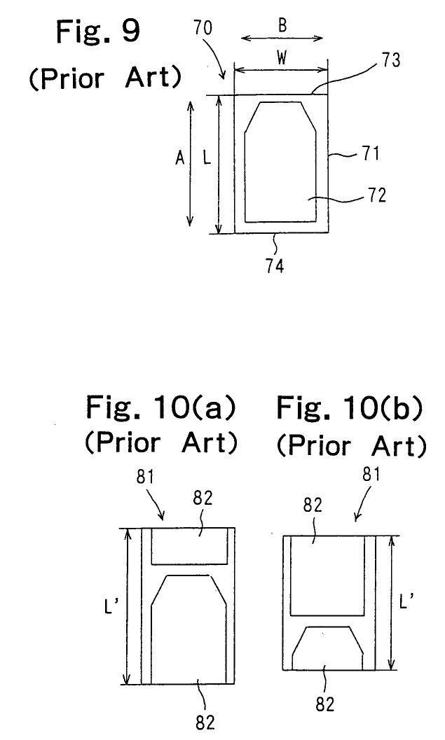

FIG. 6 is a plan view illustrating a semiconductor laser device R₄ according to Embodiment 4 of the present invention.

In the device R₄, its electrode pattern piece 33 is formed straight and does not have any markers at both of the edges of the electrode pattern piece 33 extending in the resonator-length direction of arrow A.

According to the method for manufacturing a semiconductor laser device of Embodiment 4 as well, since the electrode patterns each in the form of a continuous strip longitudinally extending in the resonator-length direction of arrow A are formed on the upper surface of the wafer in the step of forming an electrode pattern, semiconductor laser devices having different resonator lengths can be manufactured from the same wafer.

Embodiment 5

FIG. 7 is a plan view illustrating a semiconductor laser device R₅ according to Embodiment 5 of the present invention.

In the device (R₁, R₂, R₃, R₄) of Embodiments 1 to 4, the electrode pattern piece (3, 13, 23, 33) has, in the chip-width direction of arrow B, the overall width (W₁, W₂, W₃, W₄) which is set to be smaller than the chip width W of the semiconductor layer portion 1, while in the device R₅ of Embodiment 5, its electrode pattern piece 43 has, in the chip-width direction of arrow B, the overall width W₅ which is set to be equal to the chip width W of the semiconductor layer portion 1. The electrode pattern piece 43 of the device R₅ has a pair of markers 46 each in the shape of a rectangular notch at the respective edges of the electrode pattern piece 43 extending in the resonator-length direction of arrow A. The marker 46 is set so that its overall length M₅ in the resonator-length direction of arrow A is, for example, 150 μm and its maximum length N₅ in the chip-width direction of arrow B is, for example, 30 μm, so that the ratio of the overall length M₅ to the maximum length N₅ is 5:1.

According to the method for manufacturing a semiconductor laser device of Embodiment 5, an electrode pattern piece in the form of a sheet is formed on the substantially entire surface of the semiconductor wafer in the step of forming an electrode pattern. At this time, the electrode pattern piece has a plurality of rectangular openings to be markers. The openings to be markers are formed at the pitch equal to the chip width W in the chip-width direction of arrow B and at the pitch equal to the fixed resonator length L in the resonator-length direction of arrow A. These openings to be markers lie on hypothetical lines extending in the resonator-length direction of arrow A sectioning the electrode pattern at intervals each of the chip width W.

Then, the wafer thus having the electrode pattern in the form of a sheet is cut for every length equal to the fixed resonator length L into the plurality of semiconductor bars. The cutting is carried out along hypothetical lines passing halfway between the adjacent openings to be markers 46 in the chip-width direction of arrow B. Then, the bars are each sectioned into the semiconductor laser devices R₅ while sectioning each opening into two markers. The sectioning is carried out along the resonator-length direction of arrow A.

According to the method for manufacturing a semiconductor laser device of Embodiment 5 as well, since the electrode pattern in the form of a sheet extending continuously in the resonator-length direction of arrow A is formed on the wafer in the step of forming an electrode pattern, semiconductor laser devices having different resonator lengths can be manufactured from the same wafer. Moreover, the openings to be markers lie on the hypothetical lines at intervals each of the chip width W to facilitate an accurate sectioning of the semiconductor bars. In Embodiment 5, the markers 46 are formed at the pitch equal to the fixed resonator length L. Accordingly, for manufacturing semiconductor laser devices having a resonator length different from the resonator length L, it is preferred that the wafer is cut to lengths longer than the resonator length L so that devices obtained have a resonator length longer than the resonator length L.

Embodiment 6

FIG. 8 is a plan view illustrating a semiconductor laser device R₆ according to Embodiment 6 of the present invention.

In the device R₆, its electrode pattern piece 53 has, in the chip-width direction of arrow B, an overall width W₆ which is set to be equal to the width W of the semiconductor layer portion 1, as in Embodiment 5. The electrode pattern piece 53 has a marker 56 in the shape of a rectangular aperture at the center of the electrode pattern piece 53. The marker 56 is set so that its overall length M₆ in the resonator-length direction of arrow A is, for example, 200 μm and its maximum length N₆ in the chip-width direction of arrow B is, for example, 100 μm, so that the ratio of the overall length M₆ to the maximum length N₆ is 2:1.

According to the method for manufacturing a semiconductor laser device of Embodiment 6, its electrode pattern in the form of a sheet is formed on the substantially entire surface of the semiconductor wafer. At this time, a plurality of markers 56 each in the shape of a rectangular aperture are formed at the pitch equal to the fixed chip width W in the chip-width direction of arrow B at corresponding positions of laser light emitting channels in the chip-width direction of arrow B and at the pitch equal to the fixed resonator length L in the resonator-length direction of arrow A.

Then, a wafer having the electrode pattern in the form of a sheet is cut for every length equal to the fixed resonator length L into a plurality of semiconductor bars. The cutting is carried out along hypothetical lines in the chip-width direction of arrow B passing halfway between the adjacent markers. Subsequently, the bars thus obtained are each sectioned into a plurality of semiconductor laser devices. The sectioning is carried out along hypothetical lines in the resonator-length direction of arrow A passing halfway between the adjacent markers.

According to the method for manufacturing a semiconductor laser device of Embodiment 6 as well, since the electrode pattern in the form of a sheet extending continuously in the resonator-length direction of arrow A is formed on the wafer in the step of forming an electrode pattern, semiconductor laser devices having different resonator lengths can be manufactured from the same wafer. Moreover, in mounting the completed laser chip on a heat sink or a package, the marker 56 facilitates an accurate positioning of the laser light emitting channels. In Embodiment 6, the markers 56 are formed at the pitch equal to the fixed resonator length L. Accordingly, for manufacturing semiconductor laser devices having a resonator length different from the resonator length L, it is preferred that the wafer is cut to lengths longer than the resonator length L so that devices obtained have a resonator length longer than the resonator length L.

Other embodiments

(1) In the device R₅ of Embodiment 5 shown in FIG. 7, the electrode pattern piece 43 has the markers 46 which are positioned intermediate between the respective edges of the electrode pattern piece 43 extending in the resonator-length direction of arrow A, i.e., halfway between the pair of cleavage planes 4 and 5. However, in a case where the markers 46 are formed nearer one of the cleavage planes 4 and 5 (for example, the one serving as the main surface for emitting laser light) than the other cleavage plane, an easy distinction can be made of the main surface for emitting laser light from the other surfaces in packaging the resultant chip.

(2) In the device R₆ of Embodiment 6 shown in FIG. 8, both the marker 56 and the laser light emitting channel are formed at positions intermediate in the overall width W₆ of the electrode pattern piece 53. However, the laser light emitting channel may be shifted from the above-mentioned position towards one of the edges of the device R₆ extending in the resonator-length direction of arrow A, and the maker 56 may be formed at a corresponding position of that laser light emitting channel. Moreover, in a case where the marker 56 is formed nearer one of the cleavage planes 4 and 5 (for example, the one serving as the main surface for emitting laser light) than the other cleavage plane, an easy distinction can be made of the main surface for emitting laser light from the other surfaces in packaging the resultant chip.

(3) In the embodiments described so far, the shapes of the marker of the electrode pattern piece are right triangle and rectangle. However, they are limited thereto, and may be semicircle, semiellipse, semioval, isosceles triangle, equilateral triangle, square and trapezoid. Especially, in Embodiment 5 shown in FIG. 7, in a case where the marker 46 is formed as a notch in the shape of a right triangle that points the main surface for emitting laser light, an easy distinction can be made of the main surface for emitting laser light from the other surfaces in packaging the resultant chip in Embodiment 6 shown in FIG. 8, in a case where the marker 56 is shaped as an elongated sosceles triangle that points the main surface for emitting laser light, an easy distinction can be made of the main surface for emitting laser light from the other surfaces in packaging the resultant chip.

(4) In the embodiments described so far, the marker is set so that its overall length in the resonator-length direction of arrow A is set longer than its maximum length thereof in the chip-width direction of arrow B. However, the former may be set shorter than the latter. Preferably, the ratio of the former to the latter is 1:5 to 1:1.

(5) In the embodiments described so far, the semiconductor wafer having the electrode pattern is cut for every length equal to the fixed resonator length L into a plurality of semiconductor bars that extend longitudinally in the chip-width direction of arrow B. However, the wafer may be cut for every length equal to the chip width W into a plurality of semiconductor bars that extend longitudinally in the resonator-length direction of arrow A. Thereafter, the bars thus obtained may be sectioned for every length equal to the fixed resonator length into semiconductor chips with a desired size. In such a case, semiconductor bars that extend longitudinally in the resonator-length direction can be kept in stock, making it possible to respond to immediate production in small volumes of semiconductor laser devices having a different resonator length.

According to the present invention, the electrode pattern is formed on the upper surface of the semiconductor wafer so that it continuously extends in a resonator-length direction. Therefore, the wafer can be cut for every desired length equal to the resonator length into a plurality of semiconductor bars. Alternatively, the semiconductor bars can be sectioned for every desired length equal to the resonator length into a plurality of semiconductor laser devices. In other words, it is possible that semiconductor laser devices manufactured from the same wafer have different resonant lengths because the wafer has electrode patterns continuously extending in the resonator-length direction. Therefore, according to the present invention, it is possible to be flexible in response to a change in plan to production of laser chips having a different resonator length.

What is claimed is:

1. A method for manufacturing a semiconductor laser device, comprising the steps of:
forming an electrode pattern on an upper surface of a semiconductor wafer stacked at least a light emission layer;
cutting the resultant semiconductor wafer for predetermined width to yield a plurality of semiconductor bars; and
sectioning the semiconductor bars into a desired size to form semiconductor laser devices having a pair of cleavage surfaces which are parallel to a chip-width direction and distant from each other by a predetermined resonator length,
wherein the electrode pattern formed in the step of forming an electrode pattern is continuous at least in a resonator-length direction.

2. The method of claim 1, wherein a plurality of electrode patterns are formed in a plurality of rows at a fixed row pitch in a chip-width direction with a plurality of markers in a predetermined shape being formed at a pitch not greater than a resonator length at one or both of the edges of the electrode patterns extending in the resonator-length direction.

3. The method of claim 1, wherein the electrode pattern is formed on the substantially entire surface of the semiconductor wafer with a plurality of openings to be markers being formed on hypothetical lines sectioning the electrode pattern at intervals each of a chip width and at a pitch not greater than a resonator length in a resonator-length direction.

4. The method of claim 1, wherein the electrode pattern is formed on the substantially entire surface of the semiconductor wafer with a plurality of markers being formed at corresponding positions of laser light emitting channels of the electrode pattern in the chip-width direction at a pitch equal to a chip width in a chip-width direction and at a pitch not greater than a resonator length in the resonator-length direction of the electrode pattern.

5. A semiconductor laser device, comprising:
a semiconductor layer portion which includes at least a light emission layer and has a pair of cleavage surfaces which are parallel to a chip-width direction and distant from each other by a predetermined resonator length; and
an electrode pattern piece formed on an upper surface of the semiconductor layer portion,
wherein the electrode pattern piece comes in contact with the pair of cleavage planes at both of the edges of the electrode pattern piece extending in a chip-width direction.

6. The device of claim 5, wherein the electrode pattern piece has a marker or makers in a predetermined shape at one or both of the edges of the electrode pattern piece extending in a resonator-length direction.

7. The device of claim 6, wherein the markers at both of the respective edges of the electrode pattern piece extending in the resonator-length direction are symmetric with respect to a center line of the electrode pattern piece extending in the resonator-length direction and asymmetric with respect to a hypothetical line of the electrode pattern piece extending in the chip-width direction bisectioning the overall length of the marker.

8. The device of claim 6 or 7, wherein a plurality of markers are formed at a fixed pitch with the overall lengths of the plurality of markers in the resonator-length direction each being set to be equal to L/n, wherein L is a resonator length and n is an integer not smaller than one, and being set to be equal to the pitch of the markers.

9. The device of claim 5, the electrode pattern piece has a marker at a corresponding position of a laser light emitting channel.

10. The device of any one of claims 6 to 9, wherein the marker is set so that the ratio of its overall length in the resonator-length direction to its maximum length in the chip-width direction is 1:5 to 5:1.
